(19) United States
(12) Patent Application Publication
(10) Pub. No.: US 2021/0313354 A1
(43) Pub. Date: Oct. 7, 2021

(54) DISPLAY SUBSTRATE AND METHOD OF MANUFACTURING SAME

(71) Applicant: Nippon Electric Glass Co., Ltd., Shiga (JP)

(72) Inventors: Atsushi MUSHIAKE, Shiga (JP); Takashi MURATA, Shiga (JP); Tetsuya MURATA, Shiga (JP); Hiroki KATAYAMA, Shiga (JP); Kosuke KAWAMOTO, Shiga (JP); Masahiro HAYASHI, Shiga (JP)

(21) Appl. No.: 17/261,994

(22) PCT Filed: Jul. 30, 2019
(86) PCT No.: PCT/JP2019/029741

§ 371 Date: Jan. 21, 2021

(30) Foreign Application Priority Data
Jul. 31, 2018 (JP) 2018-143843

(51) Int. Cl. H01L 27/12; C03B 19/02; C03B 25/02; C03B 32/02; C03C 10/00

(52) U.S. Cl. CPC H01L 27/1218; C03B 19/02; C03C 2204/00; C03B 32/02; C03C 10/0027; C03B 25/025

(57) ABSTRACT

A display substrate of the present invention has a thermal shrinkage value of 10 ppm or less when the display substrate is increased in temperature from normal temperature to 500° C. at a temperature increase rate of 5° C./min, held at 500° C. for 1 hour, and then cooled to normal temperature at a temperature decrease rate of 5° C./min.

### TECHNICAL FIELD

The present invention relates to a display substrate and a method of manufacturing the same, and more particularly, to a display substrate for forming a TFT circuit in a flat panel display, such as a liquid crystal display or an OLED display, and a method of manufacturing the same.

### BACKGROUND ART

As is well known, a liquid crystal panel includes a color filter substrate on which a black matrix, RGB, photo spacers, and the like are formed in a pattern, and a TFT substrate on which thin film transistors (TFTs), transparent electrodes, and the like are formed in a pattern. Those substrates are bonded to each other with a sealing material applied along an outer peripheral edge portion interposed therebetween, and a liquid crystal material is sealed in a space surrounded by those substrates and the sealing material.

As a thin film transistor configured to drive a display, amorphous silicon, low-temperature polysilicon, high-temperature polysilicon, and the like have been known. In recent years, along with the spread of large liquid crystal displays, smartphones, tablet PCs, and the like, there is an increasing need for higher resolution of a display. A low-temperature polysilicon TFT can meet this need, but this technology requires a high-temperature process of from 500° C. to 600° C. However, a related-art glass substrate has a large thermal shrinkage amount before and after the high-temperature process, and hence pattern deviation of the thin film transistor is caused. Therefore, in order to increase the resolution of the display, a glass substrate with low thermal shrinkage is required.

### CITATION LIST

Patent Literature 1: JP 2018-27894 A

### SUMMARY OF INVENTION

### Technical Problem

When the strain point of the glass substrate is increased, the thermal shrinkage amount of the glass substrate is reduced (see Patent Literature 1) . However, although the current glass substrate has a high strain point, the thermal shrinkage amount thereof cannot be said to be sufficiently small, and does not completely satisfy the need for higher definition of a display.

The present invention has been made in view of the above-mentioned circumstances, and a technical object of the present invention is to devise a display substrate having a thermal shrinkage amount smaller than that of the related art, and a method of manufacturing the same.

### Solution to Problem

The inventors of the present invention have made extensive investigations. As a result, the inventors have found that the above-mentioned technical object can be achieved by regulating the thermal shrinkage of a substrate to a predetermined value or less. Thus, the inventors propose the finding as the present invention. That is, according to one embodiment of the present invention, there is provided a display substrate, which has a thermal shrinkage value of 10 ppm or less when the display substrate is increased in temperature from normal temperature to 500° C. at a temperature increase rate of 5° C./min, held at 500° C. for 1 hour, and then cooled to normal temperature at a temperature decrease rate of 5° C./min. With this, the thermal shrinkage amount of the substrate is reduced before and after a high-temperature process, and hence pattern deviation of the thin film transistor can be suppressed. The “thermal shrinkage value” is obtained by first engraving linear markings in parallel in two portions on a sheet-like sample, dividing the sample in a direction perpendicular to the markings to obtain two sample pieces, subjecting one of the sample pieces to predetermined heat treatment, arranging the sample piece subjected to the heat treatment and the sample piece not subjected to the heat treatment so that divided surfaces are aligned with each other, fixing the sample pieces with an adhesive tape, measuring a deviation amount ΔL between the markings, and finally measuring a value of ΔL/L0 as a thermal shrinkage value. Herein, the “L0” refers to the length of the sample piece before the heat treatment.

In addition, it is preferred that the display substrate according to the one embodiment of the present invention have a thermal shrinkage value of 10 ppm or less when the display substrate is increased in temperature from normal temperature to 600° C. at a temperature increase rate of 5° C./min, held at 600° C. for 10 hours, and then cooled to normal temperature at a temperature decrease rate of 5° C./min.

In addition, it is preferred that the display substrate according to the one embodiment of the present invention be made of crystallized glass. In general, a strain point is measured by preparing a fiber having a predetermined diameter from mother glass by a fiber elongation method. However, crystallized glass cannot be fiberized because of the low devitrification resistance thereof, and hence the strain point thereof cannot be measured. However, the inventors of the present invention have found that, although the strain point of the crystallized glass is unknown, the crystallized glass is less liable to be thermally shrunk in the high-temperature process, and have found that, when the crystallized glass is used for a display substrate, the crystallized glass can contribute to higher definition of a display. The crystallized glass is mainly used for cookware, such as a cooking device top plate. The crystallized glass for this purpose is transparent, has a low thermal expansion coefficient, and has a property of being less liable to be damaged by a thermal shock.

In addition, it is preferred that the display substrate according to the one embodiment of the present invention have a total light transmittance of 65% or more at a wavelength of 400 nm in terms of a sheet thickness of 1.1 mm. With this, the visible light transmittance of the substrate is increased. Therefore, the output of a light source for securing the brightness of the display is reduced, and a display with low power consumption can be manufactured.

In addition, it is preferred that the display substrate according to the one embodiment of the present invention have a thermal expansion coefficient of from −30×10⁻⁷/° C. to 30×10⁻⁷/° C. at a temperature of from 30° C. to 380° C. With this, the thermal shrinkage amount in the high-temperature process is reduced, and thermal shock resistance is also improved.

In addition, it is preferred that the display substrate according to the one embodiment of the present invention comprise as a composition, in terms of mass%, 50% to 70% of SiO₂, 10% to 30% of Al₂O₃, and 0% to 15% of Li₂O. With this, the thermal shrinkage amount in the high-temperature process is reduced, and devitrification resistance is improved, with the result that it becomes easy to form a sheet shape. Further, transparency is also improved.

In addition, it is preferred that the display substrate according to the one embodiment of the present invention be used for a TFT substrate.

According to one embodiment of the present invention, there is provided a method of manufacturing a display substrate, comprising the steps of: forming molten glass into a sheet shape, followed by cutting, to thereby obtain a display substrate; and holding the obtained display substrate at a temperature of 800° C. or more, and cooling the display substrate to room temperature at a temperature decrease rate of 200° C./h or less, to thereby reduce a thermal shrinkage value to 10 ppm or less, wherein the thermal shrinkage value means a thermal shrinkage rate when the display substrate is increased in temperature from normal temperature to 500° C. at a temperature increase rate of 5° C./min, held at 500° C. for 1 hour, and then cooled to normal temperature at a temperature decrease rate of 5° C./min.

### DESCRIPTION OF EMBODIMENTS

A display substrate of the present invention has a thermal shrinkage value of 10 ppm or less, preferably 8 ppm or less, 6 ppm or less, 4 ppm or less, or 2 ppm or less, particularly preferably 1 ppm or less, when the display substrate is increased in temperature from normal temperature to 500° C. at a temperature increase rate of 5° C./min, held at 500° C. for 1 hour, and then cooled to normal temperature at a temperature decrease rate of 5° C./min. In addition, the display substrate has a thermal shrinkage value of preferably 10 ppm or less, 8 ppm or less, 6 ppm or less, 4 ppm or less, or 2 ppm or less, particular preferably 1 ppm or less, when the display substrate is increased in temperature from normal temperature to 600° C. at a temperature increase rate of 5° C./min, held at 600° C. for 10 hours, and then cooled to normal temperature at a temperature decrease rate of 5° C./min. When the thermal shrinkage value is too large, a thermal shrinkage amount is increased before and after a high-temperature process, and hence pattern deviation of a thin film transistor is liable to occur. As a result, it becomes difficult to manufacture a high-definition display.

As a method of reducing the thermal shrinkage value, a method involving increasing the strain point of glass is generally performed. Besides this, there are given a method (1) involving performing annealing treatment for a long period of time and a method (2) involving precipitating a predetermined crystal in a glass matrix. The method (2) is preferred because the thermal shrinkage is significantly reduced due to the following points: when the predetermined crystal is precipitated, the structural relaxation of the glass proceeds; the crystallinity is increased, and the ratio of a residual glass layer is decreased; and the strain point of the residual glass phase is increased.

In the method (2), the thermal shrinkage value can be reduced by adjusting the type of a crystal to be precipitated, the crystallinity (ratio of a crystal to be precipitated), the composition of a crystal phase, the ratio of a glass phase, the composition of the glass phase, and the like. In order to reduce the thermal shrinkage value, a β-quartz solid solution and a β-eucryptite solid solution are preferred as the type of a crystal to be precipitated, and the crystallinity is preferably from 72% to 80%, particularly preferably from 73% to 79%. The “crystallinity” may be evaluated with an X-ray diffractometer (RINT-2100 manufactured by Rigaku Corporation) by a powder method. Specifically, a halo area corresponding to a mass of an amorphous component and a peak area corresponding to a mass of a crystal component are calculated, and then the crystallinity may be determined by the expression: [peak area]×100/[peak area+halo area] (%).

The display substrate of the present invention preferably comprises, as a composition, in terms of mass %, 50% to 70% of SiO₂, 10% to 30% of Al₂O₃, and 0% to 15% of Li₂O. The reasons why the contents of the components are restricted within the above-mentioned ranges are described below. In the descriptions of the ranges of the contents of the components, the expression “%” represents “mass %”.

SiO₂ is a component which forms a skeleton of glass and is also a component which forms a crystal, and the content thereof is preferably from 50% to 70%, more preferably from 60% to 70%, still more preferably from 62% to 68%. When the content of SiO₂ is decreased, the amount of SiO₂ in a residual glass phase is decreased, the strain point of the residual glass phase is decreased, and the thermal shrinkage amount is increased. In addition, in the high-temperature process, the thermal expansion coefficient tends to change due to a change in structure of the glass phase or tends to increase in a positive direction. Meanwhile, when the content of SiO₂ is increased, meltability is decreased, with the result that it becomes difficult to obtain homogeneous glass.

In the same manner as SiO₂, Al₂O₃ is a component which forms a skeleton of glass and is also a component which forms a crystal, and the content thereof is preferably from 10% to 30%, more preferably from 15% to 25%, still more preferably from 20% to 24%. When the content of Al₂O₃ is decreased, the amount of Al₂O₃ in the residual glass phase is decreased, the strain point of the residual glass phase is decreased, and the thermal shrinkage amount is increased. In addition, in the high-temperature process, the thermal expansion coefficient tends to change due to a change in structure of the glass phase or tends to increase in the positive direction. Meanwhile, when the content of Al₂O₃ is increased, the meltability is decreased, with the result that it becomes difficult to obtain homogeneous glass.

Li₂O is a glass-modifying component and is also a component which forms a crystal, and the content thereof is preferably from 0% to 15%, more preferably from 1% to 13%, still more preferably from 2% to 10%, particularly preferably from 3% to 7%. When the content of Li₂O is decreased, a desired crystal (Li₂O—Al₂O₃—SiO₂-based crystal) is not easily precipitated. Meanwhile, when the content of Li₂O is increased, the amount of Li₂O in the residual glass phase is increased, the strain point of the residual glass phase is decreased, and the thermal shrinkage amount is increased. In addition, in the high-temperature process, the thermal expansion coefficient tends to change due to a change in structure of the glass phase or tends to increase in the positive direction.

In addition to the above-mentioned components, for example, it is preferred that the following components be introduced.

Na₂O and K₂O are each a component which lowers the viscosity of glass and enhances the meltability and formability thereof. The content of each of the components is preferably from 0% to 4%, particularly preferably from 0% to 2%. When the content of each of the components is increased, the strain point of the residual glass phase is decreased, and the thermal shrinkage amount is increased. In addition, in the high-temperature process, the thermal expansion coefficient tends to change due to a change in structure of the glass phase or tends to increase in the positive direction.

MgO and ZnO are each a component which is solid solved in a crystal, and the content of each of the components is preferably from 0% to 2%, particularly preferably from 0% to 1.5%. When the content of each of the components is increased, crystals, such as spinel and gahnite, are liable to be precipitated in addition to the β-quartz solid solution or the β-eucryptite solid solution, and thermal shock resistance is liable to be decreased.

TiO₂ and ZrO₂ are each a nucleation component for precipitating a crystal, and the content of each of the components is preferably from 0% to 4%, or from 0% to 3.5%, particularly preferably from 1% to 3%. The total content of the components is preferably from 5% to 6%. When the content of each of the components is increased, glass is liable to be devitrified at the time of melting and forming, and it becomes difficult to obtain homogeneous glass. When the total content of TiO₂ and ZrO₂ is reduced, the crystallinity is lowered, and a nucleation action becomes insufficient, with the result that a crystal having a desired particle size cannot be obtained, and the β-quartz solid solution or the β-eucryptite solid solution is liable to be transformed to a β-spodumene solid solution at low temperature. As a result, it becomes difficult to obtain transparent crystallized glass, and the thermal expansion coefficient of the crystallized glass is increased, with the result that the thermal shrinkage amount of the crystallized glass is liable to be increased. Meanwhile, when the total content of TiO₂ and ZrO₂ is increased, glass is liable to be devitrified at the time of melting and forming, with the result that it becomes difficult to obtain homogeneous glass.

P₂O₅ is a component which facilitates nucleation, and the content thereof is preferably from 0% to 4%, particularly preferably from 0% to 3%. When the content of P₂O₅ is increased, the glass is liable to undergo phase separation, with the result that it becomes difficult to obtain homogeneous glass.

BaO is a component which lowers the viscosity of glass and enhances the meltability and formability thereof, and the content thereof is preferably from 0% to 2%, particularly preferably from 0% to 1.8%. When the content of BaO is increased, the glass is liable to be devitrified at the time of melting and forming, with the result that it becomes difficult to obtain homogeneous glass.

B₂O₃, SrO, CaO, and the like may be introduced up to a total content of 5% in order to enhance the meltability and the formability, and SnO₂, Cl, Sb₂O₃, As₂O₃, and the like maybe introduced up to a total content of 2% in order to enhance a fining property. When the content of each of the components is increased, the thermal expansion coefficient tends to change due to a change in structure of the glass phase or tends to increase in the positive direction in the high-temperature process. Further, a desired crystal is not easily precipitated.

Fe₂O₃ is a component to be mixed in as an impurity, and the content thereof is preferably 0.03% or less, or 0.025% or less, particularly preferably 0.02% or less. When the content of Fe₂O₃ is increased, coloring becomes strong, and a visible light transmittance is liable to be decreased.

It is preferred that the display substrate of the present invention have the following characteristics.

The thermal expansion coefficient at a temperature of from 30° C. to 380° C. is preferably from −30×10⁻⁷/° C. to 30×10⁻⁷/° C., from −25×10⁻⁷/° C. to 25×10⁻⁷/° C., from −20×10⁻⁷/° C. to 20×10⁻⁷/° C., from −15×10⁻⁷/° C. to 15×10⁻⁷/° C., from −10×10⁻⁷/° C. to 10×10⁻⁷/° C., from −8×10⁻⁷/° C. to 8×10⁻⁷/° C., from −6×10⁻⁷/° C. to 6×10⁻⁷/° C., from −4×10⁻⁷/° C. to 4×10⁻⁷/° C., or from −2×10⁻⁷/° C. to 2×10⁻⁷/° C., particularly preferably from −1×10⁻⁷/° C. to 1×10⁻⁷/° C. When the thermal expansion coefficient is outside the above-mentioned ranges, the time and effort for performing positioning of patterning in consideration of the thermal expansion in the high-temperature process based on the dimensions of the substrate at room temperature are increased, and hence film forming design becomes difficult. When the β-quartz solid solution or the β-eucryptite solid solution having a negative thermal expansion coefficient is precipitated as a main crystal in the glass matrix, and the crystallinity is regulated to from 73% to 79%, the negative thermal expansion coefficient of the crystal phase and the positive thermal expansion coefficient of the glass phase are easily cancelled out each other, and the thermal expansion coefficient is easily regulated within the above-mentioned ranges.

The total light transmittance at a wavelength of 400 nm in terms of a sheet thickness of 1.1 mm is preferably 65% or more, 70% or more, 75% or more, 80% or more, or 85% or more. When the above-mentioned total light transmittance is too low, an image on the display is liable to become unclear. Further, the output of the light source for securing predetermined brightness is increased, and the power consumption of the display is liable to be increased. When the particle diameter of the precipitated crystal, the difference in refractive index between the crystal phase and the glass phase, and the precipitation amount of crystals are appropriately controlled in the crystallized glass, the above-mentioned total light transmittance can be increased.

The density is preferably 2.60 g/cm³ or less, or 2.58 g/cm³ or less, particularly preferably 2.56 g/cm³ or less. When the density is too high, it becomes difficult to reduce the weight of the display.

The Young's modulus is preferably 85 GPa or more, 88 GPa or more, 90 GPa or more, or 92 GPa or more, particularly preferably 94 GPa or more. When the Young's modulus is too low, the deflection amount of the substrate is increased, and hence it becomes difficult to handle the substrate in a display manufacturing process and the like.

The specific Young's modulus is preferably 30 GPa/g·cm⁻³ or more, 32 GPa/g·cm³ or more, or 34 GPa/g·cm³ or more, particularly preferably 36 GPa/g·cm³ or more. The deflection amount of the substrate is increased, and hence it becomes difficult to handle the substrate in the display manufacturing process and the like. The “specific Young's modulus” is a value obtained by dividing the Young's modulus by the density.

The Vickers hardness is preferably 550 or more, or 600 or more, particularly preferably 650 or more. When the Vickers hardness is too small, the substrate is liable to be scratched. Therefore, in the display manufacturing process and the like, the substrate may be brought into contact with another member to be scratched, and there is a risk in that the image on the display may be unclear. The “Vickers hardness” refers to a value measured by a method in conformity with JIS Z2244-1992.

In the display substrate of the present invention, the sheet thickness is preferably 5 mm or less, 4 mm or less, 3 mm or less, 2 mm or less, 1 mm or less, 0.8 mm or less, 0.7 mm or less, 0.55 mm or less, or 0.5 mm or less, particularly preferably 0.4 mm or less. When the sheet thickness is too large, the mass of the display becomes excessively large. Further, it becomes difficult to apply the display substrate to existing manufacturing equipment, and the manufacturing cost of the display is liable to be increased.

The substrate size is preferably 100 mm□ or more, 150 mm□ or more, 200 mm□ or more, 300 mm□ or more, 500 mm□ or more, 800 mm□ or more, 1,000 mm□ or more, 1,500 mm□ or more, 2,000 mm□ or more, 2,500 mm□ or more, or 3,000 mm□ or more, particularly preferably 3,500 mm□ or more. When the substrate size is too small, it becomes difficult to perform multi-chamfering, and the manufacturing cost of the display is liable to be increased.

The surface roughness Ra is preferably 5 nm or less, 3 nm or less, 2 mm or less, or 1 nm or less, particularly preferably 0.5 nm or less. When the surface roughness Ra is too large, the quality of a film to be formed on the substrate surface is liable to deteriorate. Herein, the “surface roughness Ra” means a value measured by a method in conformity with SEMI D7-94 “FPD Glass Substrate Surface Roughness Measurement Method.”

The display substrate of the present invention may be manufactured as described below. First, a glass batch blended so as to have a predetermined glass composition is loaded into a continuous melting furnace and melted at a temperature of from 1,600° C. to 1,750° C. to be fined. After that, the molten glass is supplied to a forming apparatus, and then formed into a sheet shape, followed by cutting, to thereby obtain a crystallizable glass substrate. Herein, as a forming method, various forming methods, such as a float method, a press method, and a roll-out method, may be applied. Of those, a roll-out method is suitable because a devitrified crystal is less liable to be precipitated at the time of forming, and a glass substrate having a relatively large area can be produced.

Next, after the crystallizable glass substrate is held at a temperature of 800° C. or more, the crystallizable glass substrate is cooled to room temperature at a temperature decrease rate of 200° C./h or less. More specifically, the crystallizable glass substrate is subjected to heat treatment at a temperature of from 600° C. to 800° C. for a time period of from 1 hour to 10 hours to form a crystal nucleus (crystal nucleation stage), and is subjected to heat treatment at a temperature of from 800° C. to 950° C. for a time period of from 0.5 hour to 6 hours (crystal growth stage) to precipitate a crystal, to thereby obtain a crystallized glass substrate. Thus, the thermal shrinkage value is reduced. The temperature decrease rate from the temperature in the crystal growth stage to room temperature is preferably 200° C./h or less, 100° C./h or less, or 50° C./h or less, particularly preferably 30° C./h or less. When the temperature decrease rate is too high, the structural relaxation of the glass phase does not proceed, with the result that it becomes difficult to reduce a thermal shrinkage rate.

When a Li₂O—Al₂O₃—SiO₂-based crystal is precipitated as a main crystal, a Li₂O—Al₂O₃—SiO₂-based transparent crystallized glass substrate can be obtained. When a Li₂O—Al₂O₃—SiO₂-based crystallizable glass substrate is subjected to heat treatment at a high temperature of 1,000° C. or more, particularly 1,100° C. or more in the crystal growth stage, a β-spodumene solid solution crystal is precipitated as a main crystal, with the result that the crystallized glass substrate becomes cloudy. Therefore, the heat treatment temperature in the crystal growth stage is preferably 1,000° C. or less. It is preferred that the heat treatment time period in the crystal growth stage be appropriately adjusted, for example, within a range of from 0.5 hour to 6 hours so that the crystal grows sufficiently and the crystal does not become coarse.

After the crystallized glass substrate is obtained, surface polishing may be performed in order to increase the surface smoothness, and the chamfering may be performed in order to increase end face strength.

In the display substrate of the present invention, a film for preventing diffusion of an alkali component may be formed on the surface on which TFTs are formed. As an alkali component diffusion preventing film, for example, SiOx, SiN, or a combination thereof is preferred, and the thickness thereof is preferably from 100 nm to 1,000 nm, particularly preferably from 200 nm to 800 nm.

### EXAMPLES

### Example 1

The present invention is hereinafter described in detail by way of Examples. However, Examples below are merely examples, and the present invention is by no means limited to Examples below.

In Table 1, there are shown compositions and characteristics of samples used in Example.

TABLE 1

| (Mass %) | No. 1 | No. 2 | No. 3 | No. 4 |
|---|---|---|---|---|
| SiO₂ | 65.4 | 66.6 | 64.9 | 65.1 |
| Al₂O₃ | 22.2 | 22.0 | 22.4 | 21.9 |
| Li₂O | 3.7 | 3.5 | 3.9 | 2.9 |
| Na₂O | 0.4 | 0.5 | 0.2 | 0.4 |
| K₂O | 0.3 | 0.2 | 0.5 | 0.3 |
| MgO | 0.7 | 0.8 | 0.6 | 0.9 |
| CaO | | | 0.1 | 0.1 |
| SrO | | | | |
| BaO | 1.2 | 1.0 | 1.4 | 1.2 |
| ZnO | | | | 1.6 |
| TiO₂ | 2.0 | 1.7 | 2.3 | 2.0 |
| ZrO₂ | 2.2 | 2.2 | 2.0 | 2.2 |
| P₂O₅ | 1.4 | 1.3 | 1.5 | 1.4 |
| SnO₂ | 0.3 | 0.2 | 0.2 | 0.1 |
| Thermal shrinkage | 0 | 0 | 0 | 0 |
| [500° C.-1 hour] (ppm) | | | | |
| Thermal shrinkage | 2 | 2 | 2 | 2 |
| [600° C.-10 hours] (ppm) | | | | |
| α [30° C. to 380° C.] | 0.1 | −1 | 1 | 1.3 |
| (×10⁻⁷/° C.) | | | | |
| Transmittance | 78 | >75 | >66 | 85 |
| (thickness: 1.1 mm, | | | | |
| wavelength: 400 nm) | | | | |
| Density (g/cm³) | 2.546 | Unmeasured | Unmeasured | Unmeasured |
| Young's modulus (GPa) | 94 | Unmeasured | Unmeasured | Unmeasured |
| Specific Young's modulus | 36.9 | Unmeasured | Unmeasured | Unmeasured |
| (GPa/g · cm⁻³) | | | | |
| Modulus of rigidity | 38 | Unmeasured | Unmeasured | Unmeasured |
| (GPa) | | | | |
| Poisson's ratio | 0.22 | Unmeasured | Unmeasured | Unmeasured |
| Vickers hardness | 690 | Unmeasured | Unmeasured | Unmeasured |

Each of the samples in the table was prepared as described below. First, glass raw materials were blended so as to achieve the glass composition shown in the table. After the glass raw materials were mixed uniformly, the mixture was loaded into a platinum crucible and melted at 1,600° C. for 20 hours. Next, the molten glass was poured out onto a carbon surface plate and formed into a sheet shape having a thickness of 5 mm with a roller. After that, the resultant was cooled from 700° C. to room temperature at a temperature decrease rate of 100° C./h in an annealing furnace to obtain each crystallizable glass substrate.

Next, in the obtained crystallizable glass substrate, a crystal nucleus was generated in a glass matrix by heat treatment at 785° C. for 8 hours. After that, a crystal was grown from the crystal nucleus by heat treatment at 910° C. for 4 hours, and the resultant was further cooled to room temperature to obtain a crystallized glass substrate. The temperature increase rate from room temperature to 785° C. (nucleation temperature) was set to 168° C./h, the temperature increase rate from 785° C. (nucleation temperature) to 910° C. (crystal growth temperature) was set to 62° C./h, and the temperature decrease rate from 910° C. (crystal growth temperature) to room temperature was set to 29° C./h.

The thermal shrinkage value of the obtained crystallized glass substrate was measured as described below. First, linear markings were engraved in parallel in two portions on the crystallized glass substrate. Then, the crystallized glass substrate was divided in a direction perpendicular to the markings to obtain two crystallized glass pieces. Next, one of the crystallized glass pieces was increased in temperature from normal temperature to 500° C. at a temperature increase rate of 5° C./min, held at 500° C. for 1 hour, and cooled to normal temperature at a temperature decrease rate of 5° C./min. Subsequently, the crystallized glass piece subjected to the heat treatment and the crystallized glass piece not subjected to the heat treatment were arranged so that divided surfaces were aligned with each other and fixed with an adhesive tape. After that, a deviation amount ΔL between the markings was measured. Finally, a value of ΔL/L0 was measured as a thermal shrinkage value. The “L0” refers to the length of the glass piece before the heat treatment. A thermal shrinkage value was measured also by increasing one of the crystallized glass pieces in temperature from normal temperature to 600° C. at a temperature increase rate of 5° C./min, holding the resultant at 600° C. for 10 hours, and cooling the resultant to normal temperature at a temperature decrease rate of 5° C./min by the same procedure.

The thermal expansion coefficient α at a temperature of from 30° C. to 380° C. is an average value measured with a dilatometer.

The total light transmittance at a wavelength of 400 nm in terms of a sheet thickness of 1.1 mm is a value measured with a spectrophotometer.

The density is a value measured by a well-known Archimedes method.

The Young's modulus, the modulus of rigidity, and the Poisson's ratio are each a value measured by a flexural resonance method. The specific Young's modulus is a value obtained by dividing the Young's modulus by the density.

The Vickers hardness is a value measured by a method in conformity with JIS Z2244-1992.

As is apparent from Table 1, Samples No. 1 to No. 4 each had a thermal shrinkage value of 0 ppm when the sample was increased in temperature from normal temperature to 500° C. at a temperature increase rate of 5° C./min, held at 500° C. for 1 hour, and then cooled to normal temperature at a temperature decrease rate of 5° C./min. Therefore, it is conceivable that Samples No. 1 to No. 4 contribute to higher definition of a display.

In Table, 2, there are shown a composition and characteristics of a sample used as Comparative Example.

TABLE 2

| (Mass %) | Comparative Example |
|---|---|
| SiO₂ | 62.4 |
| Al₂O₃ | 18.5 |
| B₂O₃ | 2.4 |
| MgO | 2.1 |
| CaO | 4.4 |
| SrO | 2.2 |
| BaO | 7.7 |
| SnO₂ | 0.2 |
| Thermal shrinkage [500° C.-1 hour] | 12 |
| α [30° C. to 380° C.] (×10⁻⁷/° C.) | 35.7 |
| Strain point (° C.) | 738 |
| Density (g/cm³) | 2.568 |
| Young's modulus (GPa) | 79 |
| Specific Young's modulus (GPa/g · cm⁻³) | 30.7 |
| Modulus of rigidity (GPa) | 32.6 |
| Poisson's ratio | 0.22 |

The sample in the table was prepared as described below. First, glass raw materials were blended so as to achieve the glass composition shown in the table. After the glass raw materials were uniformly mixed, the mixture was loaded into a continuous melting furnace and melted at 1,600° C. Next, after steps of fining, supplying, stirring, and the like, the resultant was formed into a sheet shape by an overflow down-draw method. The obtained glass substrate was evaluated for each of characteristics in the same manner as in Example. The strain point was measured based on a method of ASTM C336. The strain point was not measurable in Example but was measurable in Comparative Example.

As is apparent from Table 2, the substrate of Comparative Example had a thermal shrinkage value of 12 ppm when the substrate was increased in temperature from normal temperature to 500° C. at a temperature increase rate of 5° C./min, held at 500° C. for 1 hour, and then cooled to normal temperature at a temperature decrease rate of 5° C./min. Therefore, it is conceivable that the substrate of Comparative Example hardly contribute to higher definition of a display.

### Example 2

First, glass raw materials were blended so as to achieve the glass composition shown in Table 1. After the glass raw materials were uniformly mixed, the mixture was melted in a tank furnace. Next, the molten glass was formed into a sheet shape having a width of 2,000 mm, a length of 2,000 mm, and a thickness of 2 mm with a roll forming machine. Then, the resultant was cooled to room temperature in an annealing furnace to obtain each crystallizable glass substrate.

Next, in the obtained crystallizable glass substrate, a crystal nucleus was generated in a glass matrix by heat treatment at 785° C. for 8 hours. After that, a crystal was grown from the crystal nucleus by heat treatment at 910° C. for 4 hours, and the resultant was further cooled to room temperature to obtain a crystallized glass substrate. The temperature increase rate from room temperature to 785° C. (nucleation temperature) was set to 168° C./h, the temperature increase rate from 785° C. (nucleation temperature) to 910° C. (crystal growth temperature) was set to 62° C./h, and the temperature decrease rate from 910° C. (crystal growth temperature) to room temperature was set to 29° C./h.

Further, the obtained crystallized glass substrate was ground to a sheet thickness of 0.5 mm, and then the surface was subjected to optical polishing.

Finally, the crystallized glass substrate subjected to optical polishing was measured for a thermal shrinkage value by the same procedure as the above to obtain the same results as those shown in Table 1.

1. A display substrate, which has a thermal shrinkage value of 10 ppm or less when the display substrate is increased in temperature from normal temperature to 500° C. at a temperature increase rate of 5° C./min, held at 500° C. for 1 hour, and then cooled to normal temperature at a temperature decrease rate of 5° C./min.

2. The display substrate according to claim 1, wherein the display substrate has a thermal shrinkage value of 10 ppm or less when the display substrate is increased in temperature from normal temperature to 600° C. at a temperature increase rate of 5° C./min, held at 600° C. for 10 hours, and then cooled to normal temperature at a temperature decrease rate of 5° C./min.

3. The display substrate according to claim 1, wherein the display substrate is made of crystallized glass.

4. The display substrate according to claim 1, wherein the display substrate has a thermal expansion coefficient of from −30×10⁻⁷/° C. to 30×10⁻⁷/° C. at a temperature of from 30° C. to 380° C.

5. The display substrate according to claim 1, wherein the display substrate has a total light transmittance of 65% or more at a wavelength of 400 nm in terms of a sheet thickness of 1.1 mm.

6. The display substrate according to claim 1, wherein the display substrate comprises as a composition, in terms of mass %, 50% to 70% of SiO₂, 10% to 30% of Al₂O₃, and 0% to 15% of Li₂O.

7. The display substrate according to claim 1, wherein the display substrate is used for a TFT substrate.

8. A method of manufacturing a display substrate, comprising the steps of:
forming molten glass into a sheet shape, followed by cutting, to thereby obtain a display substrate; and
holding the obtained display substrate at a temperature of 800° C. or more, and cooling the display substrate to room temperature at a temperature decrease rate of 200° C./h or less, to thereby reduce a thermal shrinkage value to 10 ppm or less,
wherein the thermal shrinkage value means a thermal shrinkage rate when the display substrate is increased in temperature from normal temperature to 500° C. at a temperature increase rate of 5° C./min, held at 500° C. for 1 hour, and then cooled to normal temperature at a temperature decrease rate of 5° C./min.

9. The display substrate according to claim 2, wherein the display substrate is made of crystallized glass.
